(19) United States
(12) Patent Application Publication
(10) Pub. No.: US 2012/0159284 A1
(43) Pub. Date: Jun. 21, 2012

(54) SEMICONDUCTOR MEMORY DEVICE CAPABLE OF TRANSFERRING VARIOUS TYPES OF DATA

(76) Inventor: Hitoshi OHTA, Yokohama-shi (JP)

(21) Appl. No.: 13/288,430

(22) Filed: Nov. 3, 2011

(30) Foreign Application Priority Data
Dec. 21, 2010 (JP) 2010-284496

(51) Int. Cl. G11C 29/00; G06F 11/16

(52) U.S. Cl. 714/763; 714/E11.055

(57) ABSTRACT

According to one embodiment, a semiconductor memory device includes a memory cell array, a buffer unit, an error correction unit, a data transfer unit, a memory unit, a data input/output unit, a data bus, and a control unit. The control unit controls a first operating mode in which the memory unit is used and a second operating mode in which the memory unit is not used. In the second operating mode, the data transfer unit transfers the data supplied to the input/output unit through the data bus, to the data buffer unit, transfers the data transferred to the data buffer, to the error correction unit and transfers parity data generated in the error correction unit, to the buffer unit.

### CROSS-REFERENCE TO RELATED APPLICATIONS

This application is based upon and claims the benefit of priority from prior Japanese Patent Application No. 2010-284496, filed Dec. 21, 2010, the entire contents of which are incorporated herein by reference.

### FIELD

Embodiments described herein relate generally to a semiconductor memory device including, for example, NAND flash memories.

### BACKGROUND

The NAND flash memory is known as a nonvolatile semiconductor memory. Recently, memories have been developed, each incorporating a NAND flash memory and a static random access memory (SRAM). Further, a NAND flash memory has been developed, which performs error checking and correction (ECC) on data. It is therefore desired that in this NAND flash memory, various types of data should be transferred.

### BRIEF DESCRIPTION OF THE DRAWINGS

FIG. 1 is a block diagram of a semiconductor memory device according to an embodiment;

FIG. 2 is a circuit diagram showing an exemplary NAND cell array for use in the memory device of FIG. 1;

FIG. 3 is a diagram schematically showing an exemplary data transfer unit for use in the memory device of FIG. 1;

FIG. 4 shows a schematic configuration, explaining how the embodiment operates;

FIG. 5 is a timing chart explaining how the embodiment operates as shown in FIG. 4;

FIG. 6 shows a schematic configuration, explaining how the embodiment operates in another manner;

FIG. 7 is a timing chart explaining how the embodiment operates as shown in FIG. 6;

FIG. 8 is another timing chart explaining how the embodiment operates as shown in FIG. 6; and

FIG. 9 is still another timing chart explaining how the embodiment operates as shown in FIG. 6.

### DETAILED DESCRIPTION

In general, according to one embodiment, a semiconductor memory device includes a memory cell array, a buffer unit, an error correction unit, a data transfer unit, a memory unit, an input/output unit, a data bus, and a control unit. The memory cell array includes a plurality of nonvolatile memory cells. The buffer unit temporarily holds the data to be written to the memory cell array or the data read from the memory cell array. The error correction unit corrects the errors in the data read from the memory cell array. The data transfer unit is located between the buffer unit and the error correction unit and controls data transfer. The memory unit holds the data to be written to the memory cell array or the data read from the memory cell array. The input/output unit is configured to input and output data. The data bus connects the input/output unit and the data transfer unit. The control unit controls the operating mode of the memory device, setting the device to the first operating mode in which the memory unit is used or to the second operating mode in which the memory unit is not used. In the second operating mode, when data is written to the memory cell array, when data is written, the data transfer unit transfers the data supplied from the input/output unit through the data bus, to the buffer unit, transfers the data transferred to the buffer unit to the error correction unit, and transfers the parity data generated in the error correction unit, to the buffer unit.

Embodiments will be described with reference to the accompanying drawings. In the following description, any identical components are designated by the same reference number.

### <Overall Configuration of the Memory System>

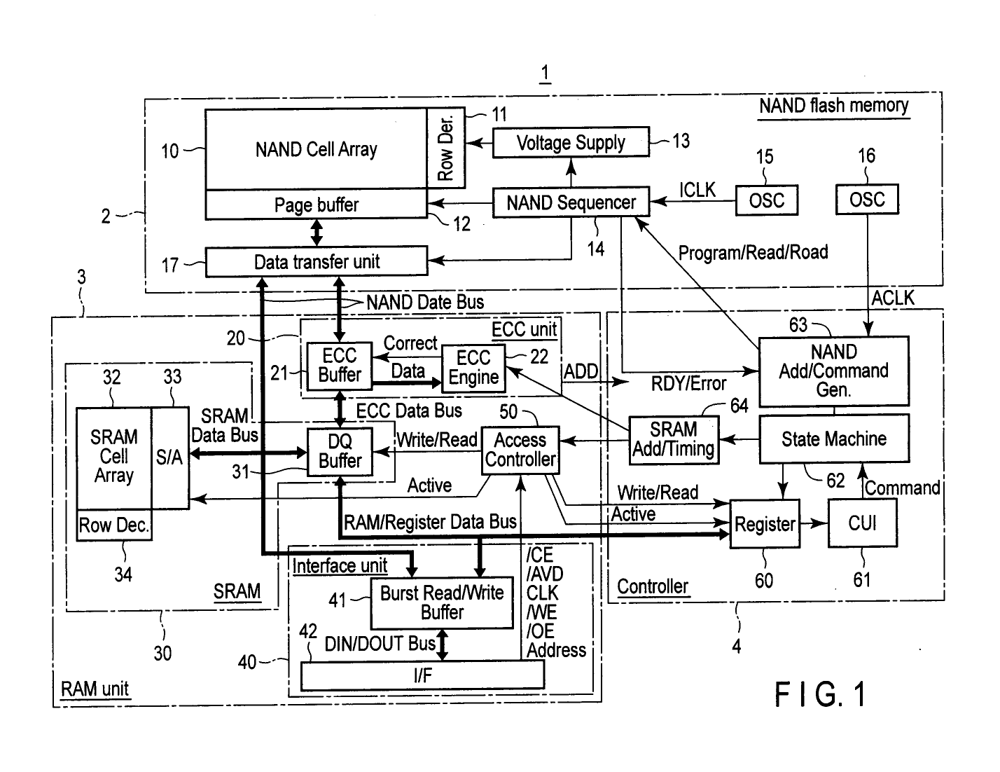

FIG. 1 is a block diagram of the semiconductor memory device (memory system) 1 according to an embodiment. The memory system 1 comprises a NAND flash memory 2, a RAM unit 3 as a memory unit, and a controller 4. The NAND flash memory 2, RAM unit 3 and controller 4 are formed on the same semiconductor substrate, constituting one IC chip.

### <NAND Flash Memory 2>

The NAND flash memory 2 functions as main memory unit of the memory system 1. The NAND flash memory 2 comprises a memory cell array (NAND Cell Array) 10, a row decoder (Row Dec.) 11, a page buffer 12, a voltage generating circuit (Voltage Supply) 13, an NAND sequencer 14, oscillators (OSCs) 15 and 16, and a data transfer unit 17.

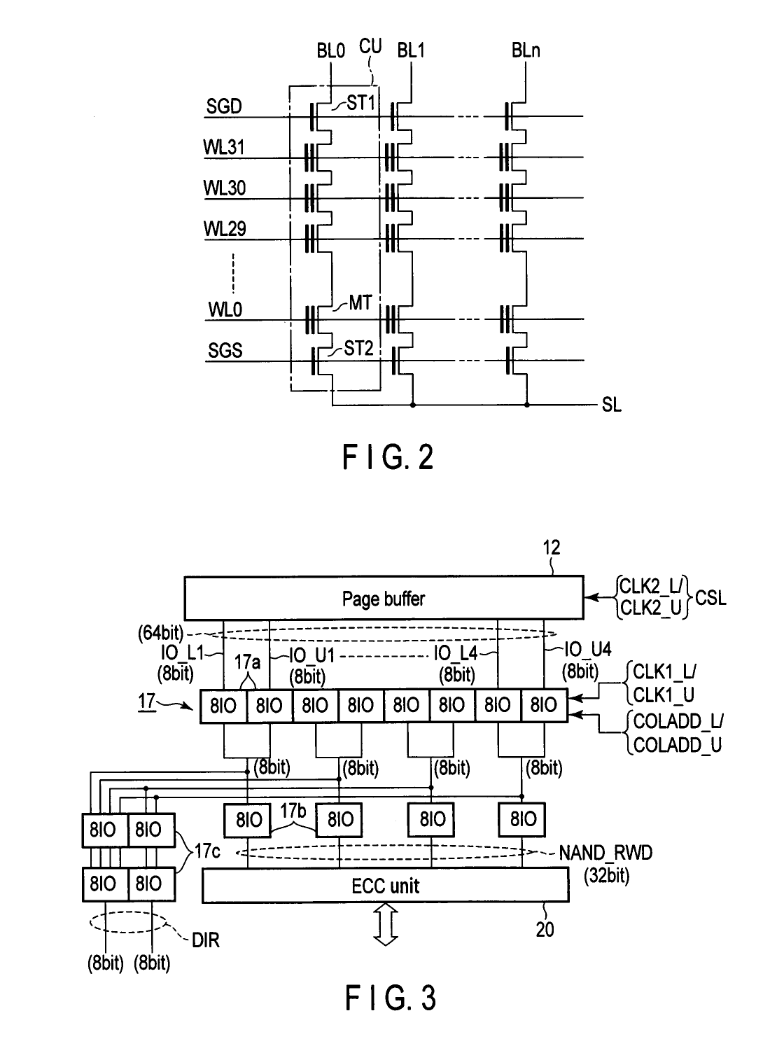

FIG. 2 shows an example of the memory cell array 10. The memory cell array 10 comprises a plurality of memory cell units CU. Each memory cell unit CU is composed of, for example, 32 memory cell transistors MT and two select transistors ST1 and ST2. Each memory cell transistor MT has a charge accumulation layer (e.g., a floating gate electrode) formed on a gate insulating film provided on a semiconductor substrate, and a control gate electrode formed on an inter-gate insulating film provided on the charge accumulation layer. Thus, the memory cell transistor MT has a laminated gate structure. Alternatively, the memory cell transistor MT may have a metal oxide nitride oxide silicon (MONOS) structure in which a nitride film functions as charge accumulation layer and traps electrons.

The current paths of adjacent memory cell transistors MT are connected in series, forming a serial transistor circuit. The memory transistor at one end of this transistor circuit has its drain connected the source of select transistor ST1. The memory transistor at the other end of the transistor circuit has its drain connected the drain of select transistor ST2.

The memory transistors MT arranged in any row have their control gate electrodes connected to one of word lines WL0 to WL31. Select transistors ST1 arranged in a row have their gates connected to a select gate line SGD. Similarly, select transistors ST2 arranged in a row have their gates connected to a select gate line SGS. Select transistors ST1 arranged in a row have their drains connected to bit lines BL0 to BLn (n being an integer of 1 or greater), respectively. Select transistors ST2 arranged in a row have their sources connected to a source line SL.

Any memory cell transistors MT connected to the same work line WL constitute a page. Data is written and read, altogether at a time, to and from the memory transistors MT constituting one page. Further, data of a plurality of pages can be erased at a time. Units of data, each so erased, is called “memory block.” Only one memory block is shown in FIG. 2. Nonetheless, the memory cell array 10 includes a plurality of memory blocks.

Each memory cell transistor MT can store one bit of data as the threshold voltage changes when electrons are injected into the floating gate electrode. The threshold voltage may be minutely controlled, thereby to store at least two bits of data in each memory transistor MT.

The row decoder 11 shown in FIG. 1 first selects one of the word lines WL0 to WL31 and the select gate line SGD or the select gate line SGS and then applies a prescribed voltage to the selected word line and select gate line, in order to write, read or erase data.

The page buffer 12 is configured to hold data of the same size as any one-page data stored in the memory cell array 10. That is, the pager buffer 12 temporarily holds one page of data read from the memory cell array 10 or one page of data to be written to the memory cell array 10. Moreover, the page buffer 12 is configured to supply 64-bit data contained in one-page data, which has been addressed, to the data transfer unit 17, and to receive 64-bit data from the data transfer unit 17. Furthermore, the page buffer 12 includes a sense amplifier that writes data to the memory cell array 10 and reads data from the memory cell array 10.

The voltage generation circuit 13 generates a voltage for writing, reading and erasing data and supplies the voltage to the row decoder 11, etc.

The NAND sequencer 14 controls the other components of the NAND flash memory 2. That is, NAND sequencer 14 receives various commands from the controller 4. In response to these commands, the NAND sequencer 14 performs an operation sequence, writing, reading and erasing data. Further, the NAND sequencer 14 controls the voltage generation circuit 13 and the page buffer 12 in various operation sequences.

The oscillator 15 generates an internal clock signal ICLK and supplies the internal clock signal ICLK to the NAND sequencer 14. The NAND sequencer 14 operates in synchronism with the internal clock signal ICLK. Further, the NAND sequencer 14 generates several clock signals (i.e., CLK1_L, CLK1_U, CLK2_L and CLK2_U, later described) from the internal clock signal ICLK, and supplies these clock signals to the data transfer unit 17.

The oscillator 16 generates an internal clock signal ACLK and supplies the internal clock signal ACLK to the controller 4 and the RAM unit 3. The internal clock signal ACLK is a reference clock signal, in accordance with which the controller 4 and the RAM unit 3 operate.

The data transfer unit 17 controls the data transfer between the page buffer 12 and the RAM unit 3. More specifically, the data transfer unit 17 controls the data transfer between the page buffer 12 and an ECC unit 20 and also the data transfer between the page buffer 12 and an interface (I/F) unit 40. To accomplish these data transfers, the data transfer unit 17 has a plurality of buses and a plurality of latch circuits, and receives a clock signal from the NAND sequencer 14.

### <RAM Unit 3>

The RAM unit 3 comprises an ECC unit 20, a static random access memory (SRAM) 30, an interface unit 40, and an access controller 50.

In the memory system 1, the NAND flash memory 2 functions as main memory unit and the SRAM 30 functions as memory buffer. Therefore, to read data from the NAND flash memory 2, the data read from the memory cell array 10 is first stored into the SRAM 30 through the page buffer 12 and then transferred to the interface unit 40, and finally output from the memory system 1.

To store data in the NAND flash memory 2, the data externally input is first stored into the SRAM 30 through the interface unit 40. Thereafter, the data stored in the SRAM 30 is transferred to the page buffer 12 and then written to the memory cell array 10.

In the description that follow, the process of reading data read from the memory cell array 10 and transferring it to the SRAM 30 through the page buffer 12 will be referred to as “load process” on data, and the process of reading data from the SRAM 30 and transferring it to an interface 43 through the buffer 41 provided in the interface unit 40 will be referred to as “read process” on data.

The process of transferring the data that should be stored in the NAND flash memory 2, from an interface 42 to the SRAM 30 through the buffer 41 will be referred to as “write process” on data. Further, the process of writing the data stored in the SRAM 30 to the memory cell array 10 through the page buffer 12 will be referred to as “program process” on data.

### <ECC Unit 20>

The ECC unit 20 performs error checking and correcting (ECC). That is, during the load process, the ECC unit 20 detects errors, if any, in the data read from the NAND flash memory 2. Further, during the program process, the ECC unit 20 generates parity data for the data to be programmed. The ECC unit 20 comprises an ECC buffer (ECC Buffer) 21 and an ECC engine (ECC Engine) 22.

The ECC buffer 21 is connected by a NAND data bus to the data transfer unit 17, and connected by an ECC bus to the SRAM 30. The ECC buffer 21 temporarily stores data for an ECC process (i.e., process of correcting during the load process or generating parity data during the program process). The ECC buffer 21 is connected by a 32-bit data bus to the data transfer unit 17. The ECC engine 22 uses the data held in the ECC buffer 21, performing the ECC process. More precisely, the ECC engine 22 first reads the data from the ECC buffer 21, then corrects the data and finally inputs the corrected data, back to the ECC buffer 21.

Moreover, in an ECC-added NAND mode (described later), the ECC unit 20 generates parity data for the data transferred from the interface 42 to the page buffer 12, when data is written. When data is read, the ECC unit 20 detects and correct errors, if any, in the data transferred to the page buffer 11. If errors are detected in the data, the ECC unit 20 transfers the address of the data containing the errors, to the controller 4.

### <SRAM 30>

The SRAM 30 functions as buffer memory for the NAND flash memory 2. The SRAM 30 comprises a DQ buffer (DQ Buffer) 31, a memory cell array (SRAM Cell Array) 32, a sense amplifier (S/A) 33, and a row decoder (Row Dec.) 34. The DQ buffer 31 temporarily stores the data to be written to the memory cell array 32 or the data read from the memory cell array 32, during the load process, during the read process, during the write process and during the program process. The memory cell array 32 has a plurality of SRAM cells (not shown). The sense amplifier 33 detects and amplifies the data read from the SRAM cells, and functions as a load in the process of writing the data stored in the DQ buffer 31 to the SRAM cells. The row decoder 34 selects some of the word lines provided in the memory cell array 32.

### <Interface Unit 40>

The interface unit 40 comprises a burst read/write buffer (Burst Read/Write Buffer) 41 and an interface 42.

The interface 42 transfers data and various signals, such as control signals and addresses, between the memory system 1 and a host apparatus outside the memory system 1. Examples of the control signals are a chip enable signal /CE for enabling the entire memory system 1, an address valid signal /AVD for latching an address, a burst read clock signal CLK, a write enable signal /WE enabling the write process, and an output enable signal /OE enabling the data output from the memory system 1. The interface 42 also sends, to the access controller 50, control signals coming from the host apparatus, such as a write request signal and a read request signal.

The buffer 41 is connected to the interface 42 by, for example, a 16-bit DIN/DOUT bus (Bus). The buffer 41 temporarily stores the data read from the NAND flash memory 2 or the data to be written to the NAND flash memory 2.

### <Access Controller 50>

The access controller 50 receives control signals and addresses from the interface 42 and controls the SRAM 30 and the controller 4 to meet the demands of the host apparatus. To be more specific, the access controller 50 activates the SRAM 30 or the register 60 (described later) incorporated in the controller 4 in response to a request coming from the host apparatus. Further, the access controller 50 issues a write command (write) or a read command (read) to the SRAM 30 or the register 60. The SRAM 30 and the register 60, so controlled, start operating.

### <Controller 4>

The controller 4 controls the other components of the memory system 1. The controller 4 comprises a register 60, a command user interface (CUI) 61, a state machine (State Machine) 62, a NAND address/command generating circuit (NAND Add/Command Gen.) 63, and a SRAM address/timing circuit (SRAM Add/Timing) 64.

The register 60 is used to set the operating state of any function in accordance with a command coming from the access controller 50. More specifically, the register 60 holds, for example, a read command and a write command.

When the register 60 holds a command, the command user interface 61 recognizes that a function execution command has been given to the memory system 1 and then sends an internal command signal (command) to the state machine 62.

The state machine 62 controls the operation sequence of the memory system 1 on the basis of the internal command sent from the command user interface 61. The state machine 62 supports many functions, such as read, write and erase. The state machine 62 controls the NAND flash memory 2 and the RAM unit 3, causing them to perform these functions.

The NAND address/command generation circuit 63 controls the NAND flash memory 2 under the control of the state machine 62. More precisely, the circuit 63 generates an address and a command (write, read or load) and sends them to the NAND flash memory 2. The NAND address/command generation circuit 63 outputs the address and the command in synchronism with the internal clock signal ACLK generated by the oscillator 16.

The SRAM address/timing circuit 64 controls the RAM unit 3 as it is controlled by the state machine 62. To be more specific, the RAM unit 3 issues an address and a command, which are sent to the access controller 50 and the ECC engine 22.

The commands supplied from the host apparatus that is provided outside the memory system 1 are supplied to the register 60 through, for example, the interface 42 and buffer 41. The commands held in the register 60 are supplied via the command user interface 61 to the state machine 62, as described above.

### <Operation of the Memory System 1>

How the memory system 1 operates will be explained below.

The memory system 1 has a first operating mode (OneNAND mode [trademark]) and a second operating mode (ECC-including NAND mode). In the OneNAND mode, data is transferred between the NAND flash memory 2 and the host apparatus through the SRAM 30. In the ECC-added NAND mode, the data is transferred between the NAND flash memory 2 and the host apparatus, not through the SRAM 30.

In the ECC-add NAND mode, the data read from the NAND flash memory 2 is held in the page buffer 12, supplied to the ECC unit 20, corrected in the ECC unit 20, and stored back into the page buffer 12. Thereafter, the data is sent from the page buffer 12 to the interface unit 40. The data coming from the host apparatus (i.e., data from the interface unit 40) is held in the page buffer 12 and transferred to the ECC unit 20. The ECC unit 20 generates parity data, which is added to the data held in the page buffer 12. The data containing the parity data is sent to the NAND flash memory 2. This data transfer is accomplished by the data transfer unit 17.

The method of transferring data differs in accordance with whether the memory system 1 operates in the ECC-added NAND mode or the OneNAND mode. Hence, the data processes are defined in one way for the OneNAND mode, and in another way for the ECC-added NAND mode. That is, in the OneNAND mode, the load process is performed, transferring data from the memory cell array 10 to the SRAM 30, the read process is performed, transferring data from the SRAM 30 to the interface unit 40, the write process is performed, transferring data from the interface 42 to the SRAM 30, and the program process is performed, writing the data stored in the SRAM 30 to the memory cell array 10.

In the ECC-added NAND mode, no data transfer is performed through the SRAM 30. That is, in ECC-added NAND mode, the read process, the program process (also called “write” in some cases) and the erase process are performed as a NAND flash memory of the ordinary type.

In the OneNAND mode, to store data from the host apparatus into the NAND flash memory 2, the data is first stored into the SRAM 30 in accordance with the read command and the address of the SRAM 30, both supplied from the host apparatus. Thereafter, the data stored in the SRAM 30 is written at a time, in units of pages, to the NAND flash memory 2 in accordance with the program command and the address of the NAND flash memory 2, both supplied from the host apparatus.

Also in the OneNAND mode, to read data from the NAND flash memory 2 by the host apparatus, the data is first read from the NAND flash memory 2 in accordance with the load command, the address of the NAND flash memory 2 and the address of the SRAM 30, all coming from the host apparatus. The data, thus read, is stored to the SRAM 30. Thereafter, the data held in the SRAM 30 is sent via the interface unit 40 to the host apparatus in accordance with the read command and the address of the SRAM 30, both coming the host apparatus.

In the ECC-added NAND mode, on the other hand, Alto store data to the NAND flash memory 2 from the host apparatus, parity data is added to the data input to the interface unit 40 in accordance with the program command and the address of the NAND flash memory 2, both coming from the host apparatus, and the data is written at a time, in units of pages, to the NAND flash memory 2.

Also in the ECC-added NAND mode, in order to read the data stored in the NAND flash memory 2 to the host apparatus, the data is read from the NAND flash memory 2 in accordance with the read command and the address of the NAND flash memory 2 coming from the host apparatus. Errors, if any, in the data so read are corrected, and the data corrected is sent to the host apparatus through the interface unit 40.

### <OneNAND Mode and ECC-Added NAND Mode>

As described above, this embodiment has two operating modes, i.e., OneNAND mode and ECC-added NAND mode. In both modes, data needs to be transferred between the page buffer 12 and the ECC unit 20. This is why the embodiment has the data transfer unit 17, which transfer data between the page buffer 12 and the ECC unit 20.

In the OneNAND mode, the data transfer unit 17 transfers 64-bit data in one clock from the ECC unit 20 to the page buffer 12.

In the ECC-added NAND mode, the data transfer unit 17 performs two types of data transfer. The first type of data transfer is parity write back transfer, in which the parity data generated in the ECC unit 20 is written back to the page buffer 12. The second type of data transfer is correct transfer, in which the data corrected in the ECC 20 is written back to the page buffer 12.

In the parity write back transfer, 32-bit data is transferred in one clock, and 64-bit data is transferred at the next clock. In the correct transfer, 32-bit data is transferred in one clock.

Three methods of controlling data transfer, in which the data transfer unit 17 is used, will be explained below.

### <Data Transfer Unit 17>

FIG. 3 schematically shows the configuration of the data transfer unit 17.

The data transfer unit 17 comprises a plurality of latch circuits 17a and a data bus. Each latch circuit 17a latches, for example, 8IO (8 bits) of data.

One of any two adjacent latch circuits 17a is connected to data buses IO_L1 to IO_L4, and the other latch circuit 17a is connected to data buses IO_U1 to IO_U4. Data buses IO_L1 to IO_L4 and IO_U1 to IO_U4 are connected to the page buffer 12. Each of data buses IO_L1 to IO_L4 and IO_U1 to IO_U4 transfers 8-bit data. Latch circuit 17a connected to data buses IO_L1 to IO_L4 receives a clock signal CLK1_L and a column address COLADD_L. Latch circuit 17a connected to data buses IO_U1 to IO_U4 receives a clock signal CLK1_U and a column address COLADD_U.

The data transfer unit 17 transfers 64-bit data to the page buffer 12, and 32-bit data to the ECC 20. That is, the data transfer unit 17 transfers to the ECC 20 half the number of bits it transfers to the page buffer 12.

More specifically, each data bus NAND-RWD is connected to two latch circuits 17a provided at the EEC unit 20. That is, the data buses for the two latch circuits 17a, totaling 16 buses, constitute eight data buses NAND-RWD, which are connected by latch circuits 17b, respectively, to the ECC unit 20 (more precisely, to the ECC buffer 21). Therefore, 8-bit data is transferred between the ECC unit 20 and each latch circuit 17a of the data transfer unit 17.

To data buses NAND-RWD, 32 buses in all, data buses DIR totaling 32 buses are connected by latch circuits 17c. Data buses DIR are connected to the buffer 41 of the interface unit 40.

The page buffer 12 has storage capacity of, for example, 4 Kbytes. The page buffer 12 is composed of eight sectors (1 to 8), each sector having storage capacity of, for example, 528 bytes. Of 528 bytes, 12 bytes constitute parity data, and 4 bytes are optional. The page buffer 12 receives clock signals CLK2_L and CLK2_U, as column select signal CSL.

### <Data Transfer in the OneNAND Mode>

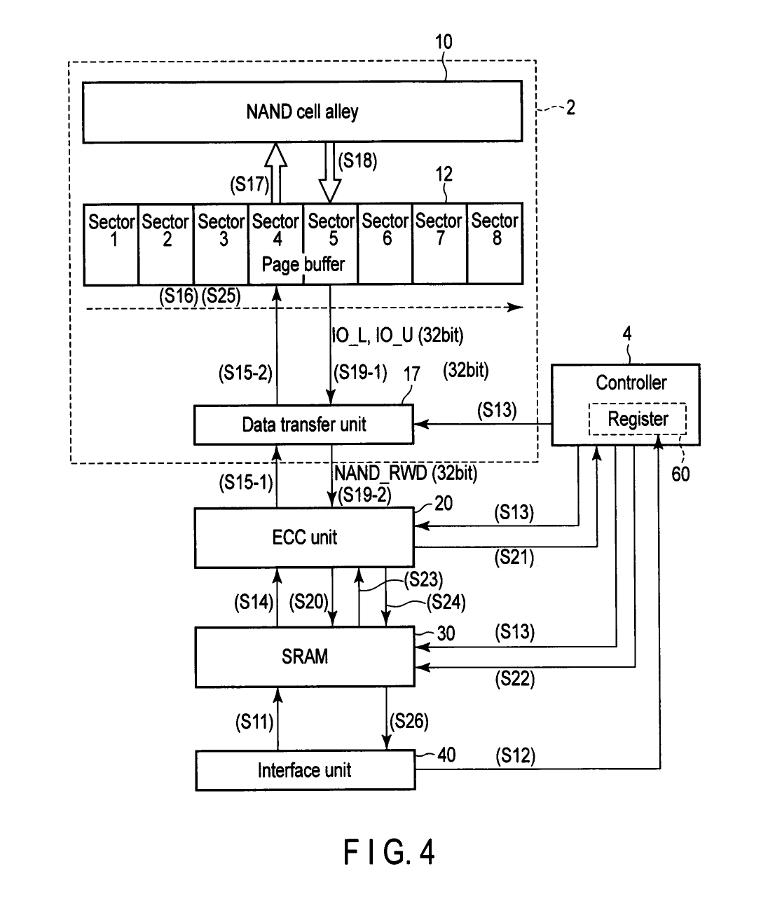

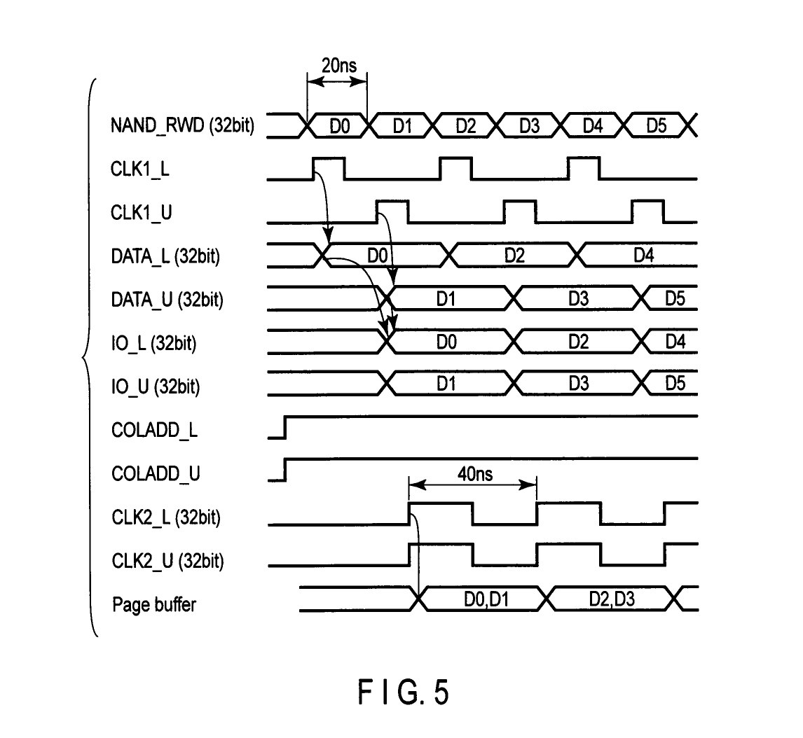

FIG. 4 schematically shows how data is transferred between the components in the OneNAND mode, and FIG. 5 is a timing chart explaining the data transfer. In FIG. 4, the components identical to those shown in FIG. 1 and FIG. 3 are designated by the same reference numbers. In FIG. 4, S11, S12, . . . indicate the order in which data and signals are transferred.

### <Program>

The program process will be explained with reference to FIG. 4 and FIG. 5. First, the interface unit 40 transfers data to the SRAM 30 in response to the data transfer command supplied from the host apparatus (not shown) (S11). Thereafter, the host apparatus input a command to the interface unit 40. The command is transferred to the register 60 (S12).

In response to the command supplied to it, the controller 4 operates as described above, generating a program command. The program command is supplied to the NAND sequencer 14. Further, the controller supplies to a control signal to the SRAM 30, EEC unit 20 and data transfer unit 17, thereby to transfer the data to be programmed (S13).

In response to the control signal, the SRAM 30 transfers the data to the EEC unit 20 (S14). This data transfer is performed 132 times, each time transferring 32 bits (totaling 32 bits×132, or 32-bit data D0, D1, . . . , D131; one sector of the page buffer 12).

The EEC unit 20 generates parity data for the data transferred from the SRAM 30. The parity data is composed of, for example, 96 bits and is added to data D129, D130 and D131 transferred from the SRAM 30. The data now added with the parity data is supplied to the data transfer unit 17, together with the main data transferred from the SRAM 30. That is, the ECC unit 20 outputs data in units of 32 bits. This data is sequentially transferred to latch circuit 17a of the data transfer unit 17, respectively, through data buses NAND-RWD, in accordance with clock signals CLK1_L and CLK1_U (S15-1).

More specifically, as shown in FIG. 5, data D0 is transferred to latch circuit 17a of the data transfer unit 17 through data bus NAND_RWD in accordance with clock signal CLK1_L, and data D1 is transferred to latch circuit 17a of the data transfer unit 17 through data bus NAND_RWD in accordance with clock signal CLK1_U. The other data D2, . . . , D129, D130 and D131 are then sequentially transferred in accordance with clock signals CLK1_L and CLK1_U.

The data transferred to latch circuit 17a of the data transfer unit 17 is transferred to the page buffer 12 in accordance with clock signals CLK2_L and CLK2_U and the column addresses COLADD_L and COLADD_U (S15-2).

To be more specific, while the column addresses COLADD_L and COLADD_U remain at high level, data D0 and D1 in the two latch circuits 17a is transferred to the page buffer 12 through data buses IO_L1 to IO_L4 and data buses IO_U1 to IO_U4 in accordance with clock signal CLK2_L. That is, in accordance with clock signals CLK2_L and CLK2_U, the 64-bit data D0 and D1 held in two latch circuits 17a, respectively, are transferred to the page buffer 12. Next, in accordance with clock signal CLK2_U, the 64-bit data D2 and D3 held in the two latch circuits 17a, respectively, in accordance with clock signals CLK2_L and CLK2_U, are transferred to the page buffer 12.

The sequence described above can be programmed while the data remains held in the two latch circuits 17a of the data transfer unit 17. Therefore, the cycle of clock signals CLK2_L and CLK2_U supplied to the page buffer 12 is, for example, 40 ns if clock signals CLK1_L and CLK1_U used to supply data to latch circuits 17a has a cycle of, for example, 20 ns.

The processes S14 and S15 described above are repeated in accordance with clocks signals CLK2_L and CLK2_U, for the selectors 1 to 8 of the page buffer 12 (S16).

After the data and the parity data have been transferred to the sections 1 to 8 of the page buffer 12, the data and parity data, both held in the page buffer 12, are written to the memory cell array 10 in the program process (S17).

### <Load>

The load process of reading data from the memory cell array 10 will be explained. If the host apparatus supplies data for generating a load command, this data is supplied to the register 60 incorporate in the controller 4 (S12). The controller 4 generates a load command in accordance with this data. The load command is supplied to the NAND sequencer 14. The NAND sequencer 14 generates column addresses COLADD_L and COLADD_U, which are supplied to the page buffer 12, etc. The one-page data read from the memory cell array 10 is transferred to the page buffer 12 (S18).

Thereafter, the data held in the page buffer 12 is transferred to latch circuits 17a of the data transfer unit 17 in accordance with clock signals CLK1_L and CLK1_U. This data transfer is reverse to the data transfer performed in the program process. For example, the 64-bit data D0 and D1, both output from the page buffer 12, are divided, each into two 32-bit data D0 (0th to 31st bits) and D1 (32nd to 63rd bits), which are transferred (S19-1).

Data D0 and D1 transferred to the two latch circuits 17a, respectively, are transferred to the ECC unit 20, in units of 32 bits, through data buses NAND_RWD in accordance with clock signals CLK1_K and CLK2_U (S19-2).

The data, thus transferred to the ECC unit 20, is loaded to the SRAM 30 in units of 32 bits, by repeating the load process 132 times (32 bits×132 times) (S20).

While the data is being loaded, an error may be detected in the ECC unit 20. In this case, the address of the data containing this error is supplied to the controller 4 (S21). The controller 4 sends this address to the SRAM 30 (S22). The 32-bit data containing the error corresponding to the address is read from the SRAM 30 and transferred to the ECC unit 20 (S23). The ECC unit 20 corrects the error in the data transferred from the SRAM 30. The data, now free of errors, is transferred from the ECC unit 30 to the SRAM 30 (S24). In the SRAM 30, the data is stored at the address.

The sequence of steps S19-1 to S24 is repeated for the sectors 1 to 8 of the page buffer 12 (S25). Thereafter, the data stored in the SRAM 30 is read and transferred from the interface unit 40 to the host apparatus (S26).

### <Data Transfer in the ECC-Added NAND Mode>

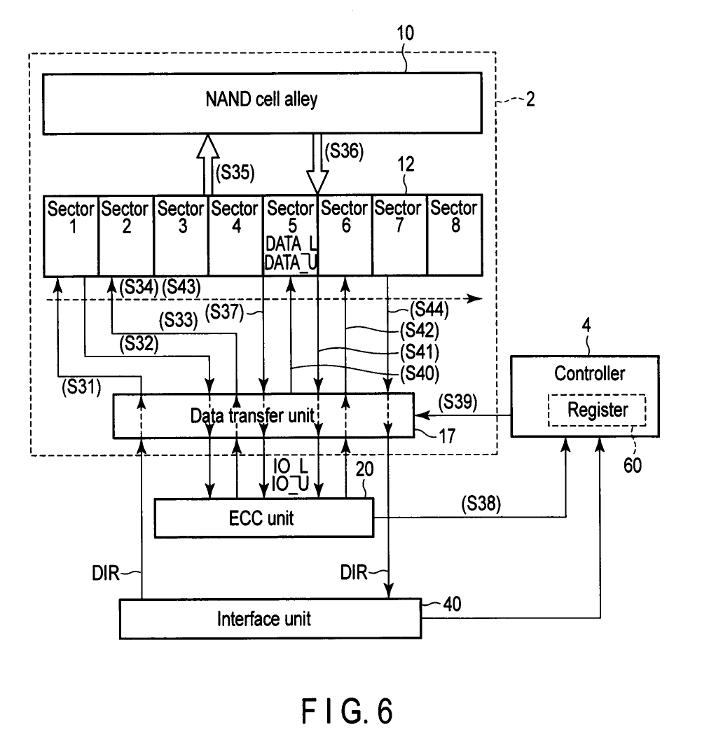

FIG. 6 schematically shows the data transfer performed in the ECC-added NAND mode. As pointed out before, the ECC-added NAND mode includes the parity write back transfer and the correct transfer. In the parity write back transfer, the parity data generated in the ECC unit 20 is written back to the page buffer 12. In the correct transfer, the data corrected in the ECC 20 is written back to the page buffer 12.

### <Parity Write Back>

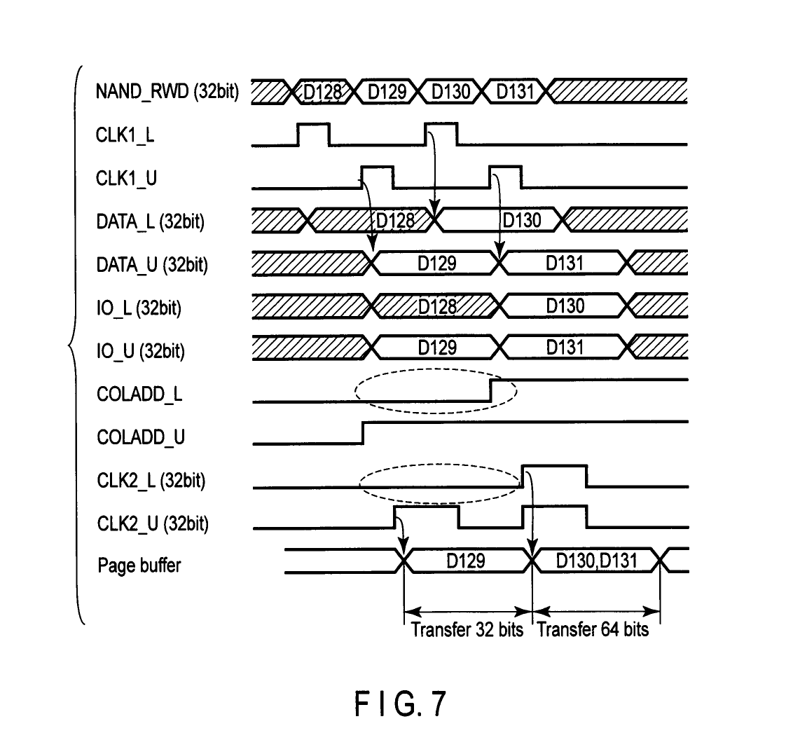

The parity write back transfer will be explained with reference to FIG. 6 and FIG. 7. In FIG. 6, the components identical to those shown in FIGS. 1 and 3 are designated by the same reference numbers, and “S31,” “S32,” . . . indicate data and the order in which the data are transferred.

In the ECC-added NAND mode, the data supplied from the host apparatus is supplied to the page buffer 12 through the data transfer unit 17. The data held in the page buffer 12 is transferred to the ECC unit 20, which generates parity data. The parity data is written back to the page data 12.

As shown in FIG. 7, each sector of the page buffer 12 contains 32-bit data D0 to D131. Of these data, data D129, D130 and D131, for example, are parity data as described above. The parity data has been generated in the ECC unit 20 on the basis of data D0 to D128. The parity data composed of items D129, D130 and D131 is written from the ECC unit 20 back to the page buffer 12.

The parity write back transfer outlined above will be described in detail. First, a command CMD(80h), an address and data are supplied from the host apparatus to the interface unit 40. The command is supplied to the register 60 incorporate in the controller 4. On the basis of this command, the controller 4 generates a control signal. The data to be written is thereby transferred from the interface unit 40 to the page buffer 12 through data buses DIR (S31). The command CMD(80h) is a write command. Note that “h” indicates that the command is a hexadecimal number. If this command is supplied to the controller 4, the data supplied from the host apparatus is transferred to the page buffer 12 via data buses DIR and latch circuits 17c of the data transfer unit 17, without passing through the EEC unit 20.

Thereafter, the host apparatus may supply a command CMD(10h) instructing that an automatic program, for example, should be executed. Then, one-sector data is transferred from the page buffer 12 through the data transfer unit 17 to the EEC unit 20. That is, 32-bit data is transferred 132 times (32 bits×132 times) via the data transfer unit 17 to the ECC unit 20. The ECC unit 20 generates parity data from the data thus transferred (S32).

Next, the parity data D129, D130 and D131 generated in the ECC unit 20 are transferred to the page buffer 12 (S33). In this case, as shown in FIG. 7, the column address COLADD_L and clock signal CLK2_L are first set to low level, inhibiting the transfer of data D128 on lower side. In this state, the column address COLADD_U is set to high level, and the 32-bit data D129 on upper side is transferred to the page buffer 12. The “data on lower side” is composed of 0th to 31st bits of the 64-bit data (composed of two 32-bit data), and the “data on upper side” is composed of 32nd to 63rd bits of the 64-bit data.

Then, the column addresses COLADD_L and COLADD_U are set to high level. As a result, 64-bit data D130 and D131, each including data on the lower side and data on the upper side, are transferred to the page buffer 12 in accordance with clock signals CLK2_L and CLK_U.

That is, the NAND sequencer 14, which is controlled by the controller 4, first generates an address and a clock signal for transferring 32 bits of parity data, i.e., half (½) the transfer unit data (64 bits). The NAND sequencer 14 then generates an address and a clock signal for transferring the transfer unit data (64 bits). In other words, the NAND sequencer 14 generates an address and a clock signal for fist transferring ⅓ of the parity data and then transferring the remaining ⅔ of the parity data.

The parity data is not limited to data D129, D130 and D131. The number of parity data items can be changed.

As described above, the parity data D129, D130 and D131 are written back to the page buffer 12 through the data transfer unit 17.

The sequence of steps S32 and S33 is repeated for the sectors 1 to 8 of the page buffer 12 (S34). The parity data is thereby added to the data to be written, for each sector of the page buffer 12. Thereafter, the data stored in the page buffer 12 is written to the memory cell array 10 in the program process (S35).

As described above, 32-bit data D126 is first transferred, and 64-bit data D130 and D131 are then transferred. To transfer 64-bit data twice, or to transfer data D128, D129, D130 and D131, the ECC unit 20 must have a register configured to hold data D128. Nonetheless, since the parity data D129, D130 and D131 are transferred as described above, additional registers need not be provided. This suppresses an increase in circuit area.

### <Correct>

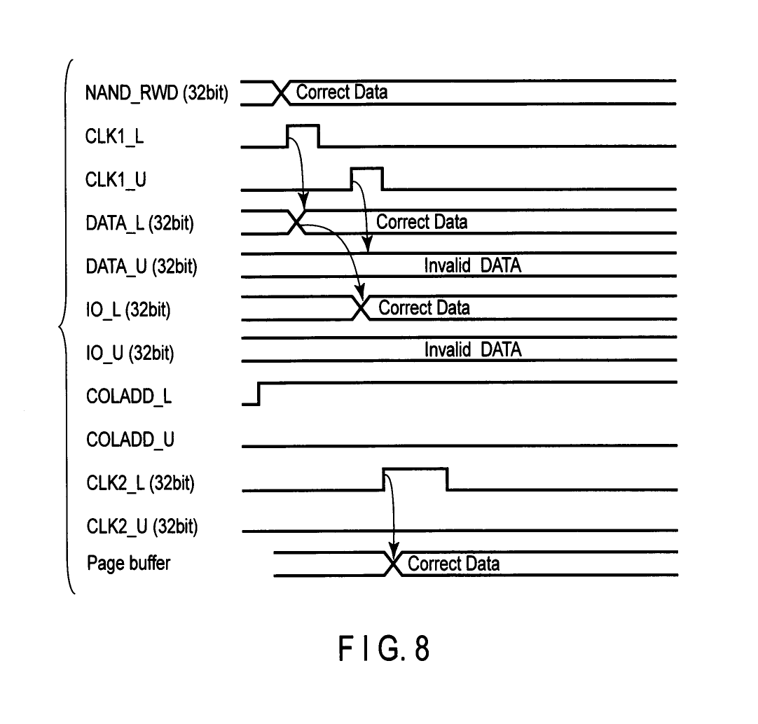

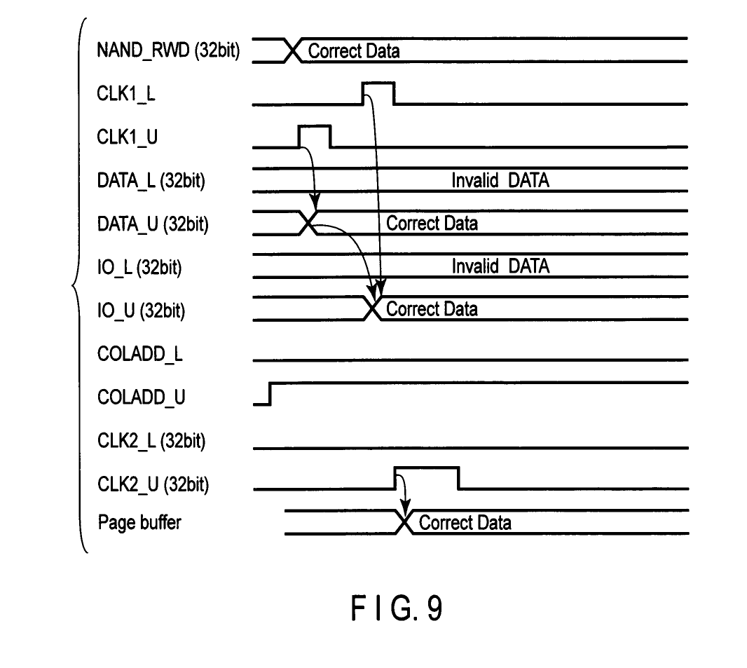

The correct transfer performed in the ECC-added NAND mode will be explained with reference to FIG. 6, FIG. 8 and FIG. 9.

For example, the data read from the memory cell array 10 in the read process is supplied to the page buffer 12. The data so read is subjected to an ECC process in the ECC unit 20, after the data has been transferred from the page buffer 12 to the ECC unit 20 through the data transfer unit 17. In the ECC unit 20, an error may be detected in the data. In this case, only the 32-bit data containing the error is corrected and written back to the page buffer 12.

To be more specific, the data is read from the memory cell array 10 to the page buffer 12 if a read command (00h-30h) is supplied from the host apparatus (S36).

Next, a process similar to the load process in the OneNAND mode is performed. That is, the data held in the page buffer 12 is read 132 times, 32 bits each time (32 bits×132 times) and is transferred to the data transfer unit 17. The data is then transferred from the data transfer unit 17 to the ECC unit 20 (S37). More precisely, the data held in latch circuits 17a of the data transfer unit 17 are transferred to the ECC unit 20 through data buses NAND_RWD, in accordance with clock signals CLK1_L and CLK1_U.

The ECC unit 20 checks each one-sector data for errors. If the ECC unit 20 detects errors in a one-sector data, the address of the data containing the errors is supplied to the controller 4 (S38).

The controller 4 supplies the error address supplied from the ECC unit 20 and a lower signal or an upper signal to the data transfer unit 17. Note that the lower signal is a signal for selecting 0th to 31st bits of the 64-bit data (composed of two 32-bit data), and the upper signal is a signal for selecting 32nd to 63rd bits of the 64-bit data.

The data transfer unit 17 holds the lower signal or the upper signal supplied from the controller 4, and transfers the address to the page buffer 12 (S40). In accordance with this address, the page buffer 12 selects the column corresponding to the 32-bit data containing the errors.

The 32-bit data selected and containing errors is transferred to the data transfer unit 17 (S41). This data is further transferred to the ECC unit 20. The ECC unit 20 corrects the errors.

If errors are detected in, for example, the data on the lower side (i.e., 0th to 31st bits), the data containing these errors is transferred to the ECC unit 20 through data buses NAND_RWD in accordance with clock signal CLK1_L. In the ECC unit 20, the errors are corrected.

As shown in FIG. 8, the data corrected in the ECC unit 20 and now free of errors is transferred to the data transfer unit 17 through data buses NAND_RWD in accordance with clock signals CLK1_L and CLK1_U. If data DATA_L on the lower side is corrected at this point, data DATA_U on the upper side will be invalidated.

Then, while the column address COLADD_U and clock signal CLK2_U remain at low level, the column address COLADDL is set to high level. Therefore, the data held in the data transfer unit 17 is transferred to the page buffer 12 through data buses IO_L1 to IO_L4 in accordance with the lock signal CLK2_L (S42). Thus, the 32-bit data corrected by the ECC unit 20 is written back to the page buffer 12.

If the ECC unit 20 corrects the errors in the data on the upper side in Step S41 as shown in FIG. 9, the data corrected will be transferred to the data transfer unit 17 through data buses NAND_RWD in accordance with clock signals CLK1_L and CLK1_U. In this case, clock signals CLK1_L and CLK1_U differ in the generation timing from the case where the data on the lower side is corrected.

That is, if the data on the lower side is corrected, clock signal CLK1_L is first generated and clock signal CLK1_U is then generated, as is shown in FIG. 8. By contrast, if the data on the lower side is corrected, clock signal CLK1_U is first generated and clock signal CLK1_L is then generated, as is shown in FIG. 9. In other words, if the data on the upper side is first corrected, clock signal CLK1_U is generated before clock signal CLK1_L. As a result, the corrected data on the upper side can be transferred, not until the timing of transferring the data on the lower side. This ensures high-speed data transfer.

Note that if data DATA_U on the upper side is corrected, data DATA_L on the lower side will be invalidated.

Next, the column address COLADD_U is set to high level while the column address COLADD_L and clock signal CLK2_L remain at low level. The corrected data held in the data transfer unit 17 is therefore transferred to the page buffer 12 through data buses IO_U1 to IO_U4, in accordance with clock signals CLK2_U (S42). The 32-bit data corrected by the ECC unit 20 is thus written back to the page buffer 12.

The sequence of Steps S37 to S42 is repeated, correcting the errors in the data of sectors 1 to 8. The data so corrected is written back to the page buffer 12 (S43).

Thereafter, the host apparatus supplies read commands and an address (i.e., CMD(05h)+ADD×2+CMD(E0h)) (where 05h and E0h are read commands) to the memory system 1. Then, the corrected data held in the page buffer 12 is transferred to the host apparatus through data buses DIR and the interface unit 40 (S44).

In the embodiment described above, the use of the data transfer unit 17 can achieve not only the program process in the OneNAND mode, but also the generation of parity data and the write back of the parity data in the ECC-added NAND mode.

Moreover, the data transfer unit 17 first transfers the 32-bit data D129, i.e., part of the 32×3-bit parity data, to the page buffer 12 by means of address control, and then transfers the remaining 64 bits, i.e., parity data D130 and D131, to the page buffer 12. A register for holding 32-bit data can therefore be dispensed with, unlike in the case where 64-bit data is transferred twice. Hence, an increase in circuit area can be prevented.

In the ECC-added NAND mode, the data transfer unit 17 writes back only the 32-bit data on the lower side or upper side, which has been corrected, to the page buffer 12 under the control of the column addresses COLADD_L and COLADD_U. This can also prevent an increase in circuit area.

Furthermore, if the ECC unit 30 corrects the errors in the data on the upper side, clock signal CLK1_U is first generated and clock signal CLK1_L is then generated. As a result, the corrected data on the upper side can be transferred, to the data transfer unit 17, without waiting the timing of transferring the data on the lower side. Hence, the data can be transferred from the ECC unit 20 to the data transfer unit 17 at high speed.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a memory cell array including a plurality of memory cells;
a buffer unit configured to hold temporarily data;
an error correction unit configured to correct errors in the data read from the memory cell array;
a data transfer unit arranged between the buffer unit and the error correction unit and configured to control data transfer;
a memory unit configured to hold the data;
a data input/output unit;
a data bus connecting the data input/output unit and the data transfer unit; and
a control unit configured to control a first operating mode in which the memory unit is used and a second operating mode in which the memory unit is not used,
wherein in the second operating mode, when data is written to the memory cell array, the data transfer unit transfers the data supplied to the input/output unit through the data bus, to the data buffer unit, transfers the data transferred to the data buffer, to the error correction unit and transfers parity data corrected in the error correction unit, to the buffer unit.

2. The device according to claim 1, wherein in the second operating mode, the data transfer unit transfers to the error correction unit the data read from the memory cell array to the buffer unit, and transfers to the buffer unit the data corrected in the error correction unit.

3. The device according to claim 2, wherein the data transfer unit transmits data to the error correction unit in unit of half (½) the number of bits constituting each data unit transferred to the data buffer.

4. The device according to claim 3, wherein the control unit generates an address for transferring half (½) the number of bits constituting the parity data generated in the error correction unit, and an address for transferring the number of bits constituting each data unit.

5. The device according to claim 4, wherein the control unit generates a clock signal for transferring the latter half of the bits constituting the corrected data to the data transfer unit, a clock signal is contemporary generated for transferring the first half of the bits constituting the corrected data to the data transfer unit.

6. The device according to claim 3, wherein in the second operating mode, the data transfer unit sequentially writes the first and latter halves of the bits constituting the corrected data, to the buffer unit.

7. The device according to claim 3, further comprising a plurality of first data buses connecting the data transfer unit and the buffer unit, and a plurality of second data buses connecting the data transfer unit and the error correction unit, the second data buses provided in half the number of the first data buses.

8. The device according to claim 7, wherein the data transfer unit includes a plurality of first latch circuits and a plurality of second latch circuits, a half of the first data buses are connected to the first latch circuits, respectively, the remaining half of the first data buses are connected to the second latch circuits, and each second data bus is connected to one first latch circuit and one second latch circuit that make a pair.

9. The device according to claim 8, wherein each of the first latch circuits is driven by a first clock signal, and each of the second latch circuits is driven by a second clock circuit.

10. The device according to claim 8, wherein the data bus includes a plurality of data buses connected to the second data buses, respectively.

11. The device according to claim 1, wherein
the control unit includes a register configured to store a command.

12. The device according to claim 11, wherein
the control unit controls the memory unit, the error correction unit, the data transfer unit based on the command stored in the register.

13. The device according to claim 10, further comprising a plurality of third latch circuits connected between the data bus and the second data buses.
